(19) United States
(12) Patent Application Publication
(10) Pub. No.: US 2016/0168704 A1
(43) Pub. Date: Jun. 16, 2016

(54) GAS INJECTORS

(71) Applicants: Ji-Hoon CHOI, Seongnam-si (KR); Young-Jin NOH, Suwon-si (KR); Joong-Yun RA, Seoul (KR); Jae-Young AHN, Seongnam-si (KR); Hun-hyeong LIM, Hwaseong-si (KR)

(72) Inventors: Ji-Hoon CHOI, Seongnam-si (KR); Young-Jin NOH, Suwon-si (KR); Joong-Yun RA, Seoul (KR); Jae-Young AHN, Seongnam-si (KR); Hun-hyeong LIM, Hwaseong-si (KR)

(21) Appl. No.: 14/963,744

(22) Filed: Dec. 9, 2015

(30) Foreign Application Priority Data
Dec. 10, 2014 (KR) 10-2014-0177175

(51) Int. Cl. C23C 16/455

(52) U.S. Cl. CPC C23C 16/45563; C23C 16/45544

(57) ABSTRACT

A gas injector may comprise: a gas introduction tube configured to introduce reaction gas into a reaction tube from a gas supply source; and/or a gas distributor connected to the gas introduction tube, extending from the gas introduction tube in a direction within the reaction tube, including a plurality of ejection holes in an inner surface of the gas distributor, and having an arc shape extending in a circumferential direction of the reaction tube. The ejection holes may be spaced apart from each other in the extending direction of the gas distributor, and are configured to spray the reaction gas.

### CROSS-REFERENCE TO RELATED APPLICATION(S)

This application claims priority from Korean Patent Application No. 10-2014-0177175, filed on Dec. 10, 2014, in the Korean Intellectual Property Office (KIPO), the entire contents of which are incorporated herein by reference.

### BACKGROUND

1. Field

Some example embodiments may relate generally to gas injectors. Some example embodiments may relate generally to wafer processing apparatuses having gas injectors. Some example embodiments may relate generally to gas injectors supplying process gases into process chambers. Some example embodiments may relate generally to wafer processing apparatuses having such gas injectors.

2. Description of Related Art

A plurality of vertically stacked wafers may be loaded into a batch reactor and then an atomic layer deposition (ALD) process may be performed to form a layer on the wafers. Especially, a blocking layer, a charge storage layer, and a tunnel insulation layer of a cell transistor of a vertical memory device such as vertical NOT AND (NAND) may be formed in the batch reactor by the ALD process.

A related art gas injector may include a cylindrical gas nozzle which extends in a vertical direction within a batch type reaction chamber. The cylindrical gas nozzle may spray a process gas on the vertically stacked wafers. However, an inner pressure and an ejection velocity may be decreased with a height in the gas injector. Accordingly, a pressure difference and an ejection velocity difference between upper and lower portions of the gas injector may be relatively great, so that a process variation may be deteriorated.

In some example embodiments, a three-dimensional (3D) memory array may be provided. The 3D memory array may be monolithically formed in one or more physical levels of arrays of memory cells having an active area above a silicon substrate, and circuitry associated with the operation of those memory cells, whether such associated circuitry is above or within such substrate. The term “monolithic” means that layers of each level of the array may be directly deposited on the layers of each underlying level of the array.

In some example embodiments, the 3D memory array may include vertical NAND (VNAND) strings that are vertically oriented such that at least one memory cell is located over another memory cell. The at least one memory cell may comprise a charge trap layer.

The following patent documents, the entire contents of which are incorporated herein by reference, describe suitable configurations for three-dimensional memory arrays, in which the three-dimensional memory array may be configured as a plurality of levels, with word lines and/or bit lines shared between levels: U.S. Pat. No. 7,679,133 B2; U.S. Pat. No. 8,553,466 B2; U.S. Pat. No. 8,559,235 B2; U.S. Pat. No. 8,654,587 B2; and U.S. Patent Publication No. 2011/0233648 A1.

### SUMMARY

Some example embodiments may provide gas injectors configured to supply process gases in order to form uniform thin layers.

Some example embodiments may provide wafer processing apparatuses having gas injectors in order to form uniform thin layers.

In some example embodiments, a gas injector may comprise: a gas introduction tube configured to introduce reaction gas into a reaction tube from a gas supply source; and/or a gas distributor connected to the gas introduction tube, extending from the gas introduction tube in a direction within the reaction tube, including a plurality of ejection holes in an inner surface of the gas distributor, and having an arc shape extending in a circumferential direction of the reaction tube. The ejection holes may be spaced apart from each other in the extending direction of the gas distributor, and are configured to spray the reaction gas.

In some example embodiments, the gas distributor may comprise an arc-shaped inner portion, spaced apart by a first radius from a center of the reaction tube, and an arc-shaped outer portion, spaced apart by a second radius greater than the first radius from the center of the reaction tube. The inner portion and the outer portion may form a distributing path for the reaction gas therebetween.

In some example embodiments, the ejection holes may be formed in the inner portion to be spaced apart from each other in the extending direction.

In some example embodiments, the ejection holes may have a circular, oval, or polygonal shape.

In some example embodiments, as height of a respective ejection hole of the plurality of ejection holes from the gas introduction tube is increased, size of the respective ejection hole may increase.

In some example embodiments, a plurality of the ejection holes may be at a same height from the gas introduction tube.

In some example embodiments, as the height of a respective ejection hole of the plurality of ejection holes from the gas introduction tube is increased, a number of the ejection holes at that same height may increase.

In some example embodiments, as height of a respective ejection hole of the plurality of ejection holes from the gas introduction tube is increased, a distance between adjacent ejection holes at that same height may be decreased.

In some example embodiments, a sectional area of a gas distributing path of the gas distributor may increase with height in the gas distributor.

In some example embodiments, the ejection holes may be configured to extend in a radial direction perpendicular to the extending direction of the gas distributor.

In some example embodiments, a wafer processing apparatus may comprise: a reaction tube extending in a vertical direction and defining a process chamber; a boat configured to be loaded into the reaction tube and configured to hold a plurality of wafers; and/or a gas injector configured to supply a reaction gas into the process chamber within the reaction tube, and comprising at least one gas distributor, extending in the extending direction of the reaction tube between the reaction tube and the boat, and having an arc shape extending in a circumferential direction of the reaction tube, and a plurality of ejection holes, formed in an inner surface of the at least one gas distributor to be spaced apart from each other in the extending direction of the at least one gas distributor and configured to spray the reaction gas.

In some example embodiments, the at least one gas distributor may comprise an arc-shaped inner portion, relatively adjacent to the boat, and an arc-shaped outer portion, spaced relatively adjacent to an inner surface of the reaction tube. The inner portion and the outer portion may form a distributing path for the reaction gas therebetween.

In some example embodiments, the inner portion may be spaced apart by a first radius from a center of the reaction tube. The outer portion is spaced apart by a second radius greater than the first radius from the center of the reaction tube.

In some example embodiments, the ejection holes may be formed in the inner portion to be spaced apart from each other in the extending direction of the at least one gas distributor.

In some example embodiments, the ejection holes may have a circular, oval, or polygonal shape.

In some example embodiments, as height of the ejection holes from a lower portion of the at least one gas distributor is increased, a size of the ejection hole may increase.

In some example embodiments, a plurality of the ejection holes may be at the same height from a lower portion of the at least one gas distributor.

In some example embodiments, as the height of the ejection hole from the lower portion of the at least one gas distributor is increased, the number of the ejection holes positioned at the same height may increase.

In some example embodiments, as a height of the ejection hole from the lower portion of the at least one gas distributor is increased, a distance between the adjacent ejection holes may decrease.

In some example embodiments, a sectional area of a gas distributing path of the at least one gas distributor may increase with a height in the at least one gas distributor.

In some example embodiments, the gas injector may further comprise a gas introduction tube connected to a lower portion of the at least one gas distributor, and/or configured to introduce the reaction gas from a gas supply source.

In some example embodiments, the wafer processing apparatus may further comprise an exhaust portion configured to exhaust gas from the process chamber.

In some example embodiments, the wafer processing apparatus may further comprise an inner tube within the reaction tube to define the process chamber.

In some example embodiments, the boat may be supported rotatably in the reaction tube.

In some example embodiments, the gas injector may comprise a first gas distributor and a second gas distributor spaced apart in the circumferential direction of the reaction tube from each other. An arc length of the first gas distributor may be the same as or different from an arc length of the second gas distributor.

In some example embodiments, a gas injector may comprise: a gas introduction tube configured to introduce reaction gas, from a gas supply source, into a reaction tube; and/or a gas distributor, configured to receive the reaction gas from the gas introduction tube and configured to distribute the reaction gas in the reaction tube via a plurality of ejection holes in the gas distributor. The ejection holes may be in an inner surface of the gas distributor. The ejection holes may be spaced apart from each other in an extending direction of the gas distributor in the reaction tube.

In some example embodiments, at least two of the ejection holes may be at a same distance along the extending direction of the gas distributor in the reaction tube.

In some example embodiments, at least two of the ejection holes may be at a same distance from the gas introduction tube.

In some example embodiments, the ejection holes may also be spaced apart from each other in a direction perpendicular to the extending direction of the gas distributor in the reaction tube.

In some example embodiments, at least two of the ejection holes may be at a same distance along the direction perpendicular to the extending direction of the gas distributor in the reaction tube.

In some example embodiments, a gas injector may comprise: a gas introduction tube configured to introduce reaction gas, from a gas supply source, into a reaction tube; and/or a gas distributor, configured to receive the reaction gas from the gas introduction tube and configured to distribute the reaction gas in the reaction tube via a plurality of ejection holes in the gas distributor. The ejection holes are in an inner surface of the gas distributor. The ejection holes are spaced apart from each other in a direction parallel to an axial direction of the reaction tube.

In some example embodiments, at least two of the ejection holes may be at a same distance along the gas distributor in the direction parallel to the axial direction of the reaction tube.

In some example embodiments, at least two of the ejection holes may be at a same distance from the gas introduction tube.

In some example embodiments, the ejection holes may also be spaced apart from each other in a direction perpendicular to the direction parallel to the axial direction of the reaction tube.

In some example embodiments, at least two of the ejection holes may be at a same distance along the direction perpendicular to the direction parallel to the axial direction of the reaction tube.

### BRIEF DESCRIPTION OF THE DRAWINGS

The above and/or other aspects and advantages will become more apparent and more readily appreciated from the following detailed description of example embodiments, taken in conjunction with the accompanying drawings, in which:

FIG. 1 is a cross-sectional view illustrating a wafer processing apparatus in accordance with some example embodiments;

FIG. 2 is a perspective view illustrating a reaction tube of the wafer processing apparatus in FIG. 1;

FIG. 3 is a perspective view illustrating a gas injector in FIG. 1;

FIG. 4 is a plan view illustrating the gas injector in the reaction tube in FIG. 1;

FIG. 5 is a cross-sectional view taken along the line A-A′ in FIG. 3;

FIG. 6 is a cross-sectional view taken along the line B-B′ line in FIG. 3;

FIGS. 7 to 11 are perspective views illustrating gas injectors in accordance with some example embodiments;

FIG. 12A is a graph illustrating an inner pressure according to a height in a related art gas injector;

FIG. 12B is a graph illustrating a gas ejection velocity according to a height in a related art gas injector;

FIG. 13A is a graph illustrating an inner pressure according to a height in a gas injector in accordance with some example embodiments;

FIG. 13B is a graph illustrating a gas ejection velocity according to a height in a gas injector in accordance with some example embodiments;

FIG. 14 is a plan view illustrating a gas injector within a reaction tube in accordance with some example embodiments;

FIG. 15 is a cross-sectional view illustrating a wafer processing apparatus in accordance with some example embodiments;

FIG. 16 is a flow chart illustrating a method of processing a wafer in accordance with some example embodiments; and

FIGS. 17 to 26 are vertical cross-sectional views illustrating a method of manufacturing a vertical memory device in accordance with some example embodiments.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will typically have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature, their shapes are not intended to illustrate the actual shape of a region of a device, and their shapes are not intended to limit the scope of the example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Reference will now be made to example embodiments, which are illustrated in the accompanying drawings, wherein like reference numerals may refer to like components throughout.

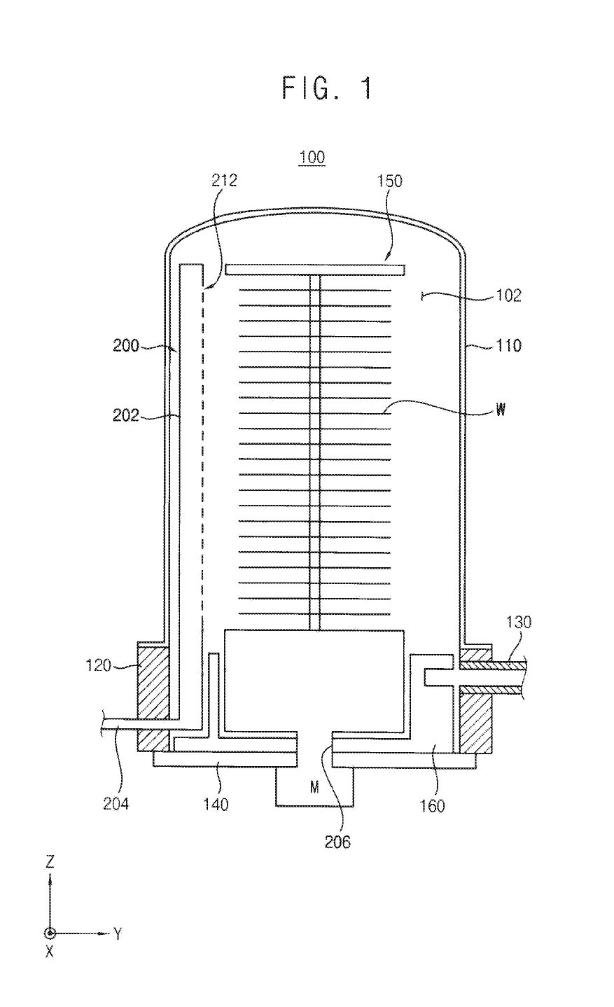

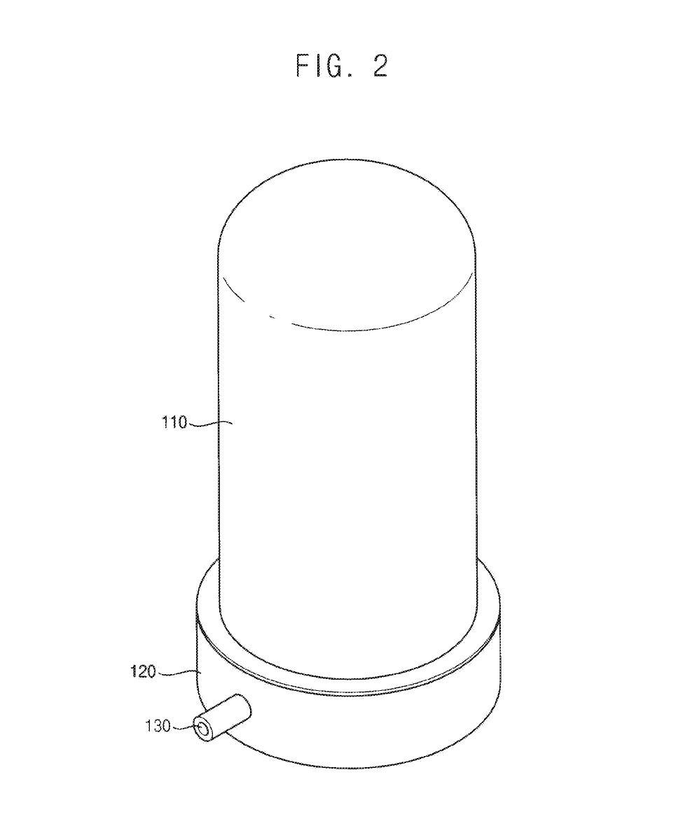

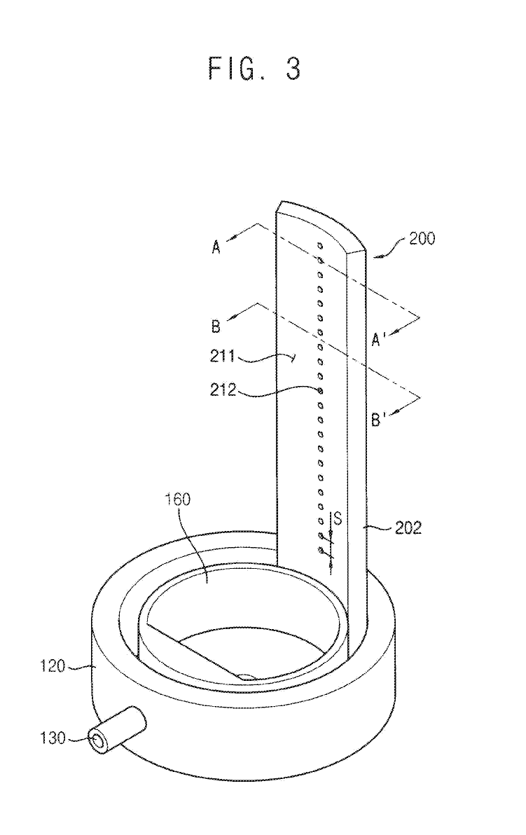

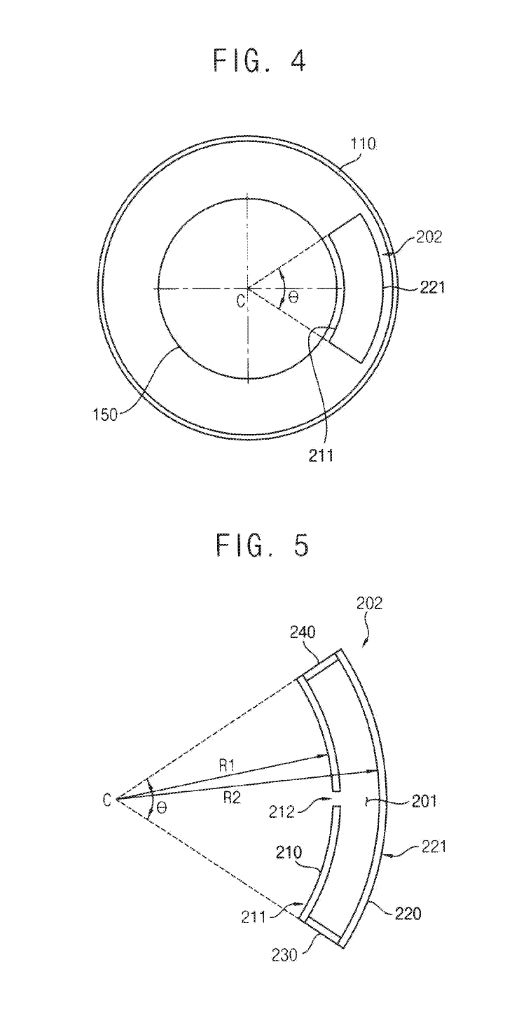

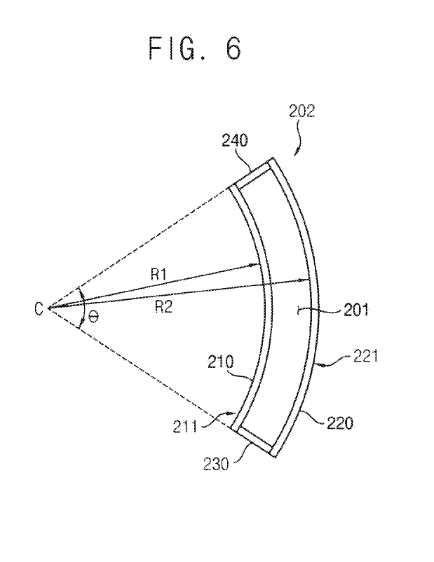

FIG. 1 is a cross-sectional view illustrating a wafer processing apparatus in accordance with some example embodiments. FIG. 2 is a perspective view illustrating a reaction tube of the wafer processing apparatus in FIG. 1. FIG. 3 is a perspective view illustrating a gas injector in FIG. 1. FIG. 4 is a plan view illustrating the gas injector in the reaction tube in FIG. 1. FIG. 5 is a cross-sectional view taken along the line A-A′ in FIG. 3. FIG. 6 is a cross-sectional view taken along the line B-B′ line in FIG. 3.

Referring to FIGS. 1 to 6, a wafer processing apparatus 100 may include a reaction tube 110 extending in a vertical direction, a boat 150 configured to be loaded into and unloaded from the reaction tube 110 and configured to support a plurality of wafers W, and a gas injector 200 configured to spray a reaction gas on the wafers W in the reaction tube 110.

In some example embodiments, the wafer processing apparatus 100 may include a vertical batch reactor. The reaction tube 110 may extend in the vertical direction (Z direction) to define a reaction chamber 102. The vertical batch reactor may receive the boat 150 that holds a plurality of the wafers W therein. The batch reactor may have benefits for efficient heating and loading sequences.

A lower portion of the reaction tube 110 may include an open end, and an upper portion of the reaction tube 110 may include a closed end. The lower open end of the reaction tube 110 may have a flange that protrudes in a radial direction. The flange may be installed in a support 120. For example, the flange of the reaction tube 110 may be connected to the support 120 by a sealing member such as O-ring to seal the reaction tube 110. Accordingly, the reaction tube 110 may extend in the vertical direction from the support 120. In addition, the reaction chamber 102 may be maintained at a desired temperature (that may or may not be predetermined) by a temperature control system such as a heater (not shown) that surrounds the reaction tube 110.

The reaction chamber 102 may receive the boat 150 that holds a plurality of the wafers W that are supported therein to be spaced apart in the vertical direction. The boat 150 may be supported on a door plate 140. The door plate 140 may move upward and downward to load and unload the boat 150 into and from the reaction tube 110. A boat cap may be disposed in a lower portion of the boat 150 to support the boat 150 and serve as a heat dissipation plate. For example, at least 25 to 150 wafers W may be stacked in the boat 150.

The door plate 140 may be positioned under the reaction tube 110 to seal the reaction tube 110. The door plate 140 may be combined with the support 120 under the reaction tube 110 by a sealing member such as O-ring to seal the reaction tube 110.

A cap plate 160 may be positioned on the door plate 140 and surround the boat cap in the lower portion of the boat 150. The cap plate 160 may be interposed between the door plate 140 and the lower portion of the boat 150 to receive the boat cap. The cap plate 160 may be arranged to face an inner surface of the support 120. For example, the cap plate 160 may include quartz, stainless steel, metal alloy, etc.

Accordingly, the cap plate 160 may prevent process gases or by-products in the reaction tube 110 from flowing into a space between the support 120 and the cap plate 160.

A height of the cap plate 160 may be determined in consideration of a size and shape of the vertical batch reactor, a process to be performed on the wafers, etc. For example, the cap plate 160 may have a height substantially the same as a height of the support 120 such that the cap plate 160 may cover an inner surface of the support 120. Alternatively, the cap plate 160 may have a height greater or smaller than the height of the support 120.

A rotational shaft may extend from the lower portion of the boat 150 may be connected to a motor M provided on an outer surface of the door plate 140 via a through hole 206 formed in the cap plate 160. Accordingly, the boat 150 on the door plate 140 may be supported rotatably in the reaction tube 110. While the boat 150 is rotated at a desired speed (that may or may not be predetermined), reaction gases may be introduced on the wafers W to perform a deposition process.

In some example embodiments, the gas injector 200 may be installed in the reaction tube 110 to supply a reaction gas onto the wafers W. The gas injector 200 may include ejection holes 212 for spraying the process gas. The process gas may be ejected toward the center of the reaction tube 110 in a horizontal plane (XY direction) parallel with principal surfaces of the wafers W.

In particular, the gas injector 200 may include a gas introduction tube 204 for introducing the reaction gas into the reaction tube 110 from a gas supply source, a gas distributor 202 connected to the gas introduction tube 204, extending from the gas introduction tube 204 in the vertical direction within the reaction tube 110 and having an arc shape extending in a circumferential direction of the reaction tube 110, and a plurality of the ejection holes 212 formed in an inner surface of the gas distributor 202 to be spaced apart from each other in the vertical direction and configured to spray the reaction gas.

The gas introduction tube 204 may penetrate the support 120 under the reaction tube 110 to extend to a guiding recess of the cap plate 160. For example, the gas introduction tube may include quartz, stainless steel, metal alloy, etc. The gas introduction tube 204 may serve as an inlet through which the reaction gas is injected into the reaction chamber 102 from the gas supply source. The gas supply source may supply a source gas for an atomic layer deposition (ALD) process. For example, the gas supply source may supply the source gas for deposition of a silicon oxide layer, silicon nitride layer, etc.

The gas distributor 202 may extend in the vertical direction of the reaction tube 110 between the boat 150 and the reaction tube 110 from the guiding recess of the cap plate 160. The gas distributor 202 may extend in the circumferential direction of the reaction tube 110 in an arc shape to surround the boat 150.

As illustrated in FIGS. 4 to 6, the gas distributor 202 may extend in the circumferential direction to form a desired central angle θ (that may or may not be predetermined) at the center C of the reaction tube 110.

The gas distributor 202 may include an arc-shaped inner portion 210, an arc-shaped outer portion 220, and first and second side portions 230 and 240 connecting the inner portion 210 and the outer portion 220. The inner portion 210 may be spaced apart by a first radius R1 from the center C of the reaction tube 110, and the outer portion 220 may be spaced apart by a second radius R2 greater than the first radius R1 from the center C of the reaction tube 110. The inner portion 210 and the outer portion 220 may form a distributing path 201 for the reaction gas therebetween.

The inner portion 210 may be spaced apart from an outer circumference surface of the boat 150, and the outer portion 220 may be spaced apart from an inner circumference surface of the reaction tube 110. An inner surface 211 of the inner portion 210 may be arranged to face the boat 150, and an outer surface 221 of the outer portion 220 may be arranged to face the inner surface of the reaction tube 110.

A plurality of the ejection holes 212 may be formed in the inner portion 210 to be spaced apart by a desired distance S (that may or may not be predetermined) from each other in the vertical direction. The ejection holes 212 may be formed to extend in a radial direction toward the boat 150, and the ejection holes 212 may be spaced apart from each other from a lower end portion of the gas distributor 202 to an upper end portion of the gas distributor 202 such that the ejection holes may spray the process gas in horizontal directions parallel with the principal surfaces of the wafers W stacked in the boat 150. For example, the ejection holes may have circular, oval, or polygonal shapes.

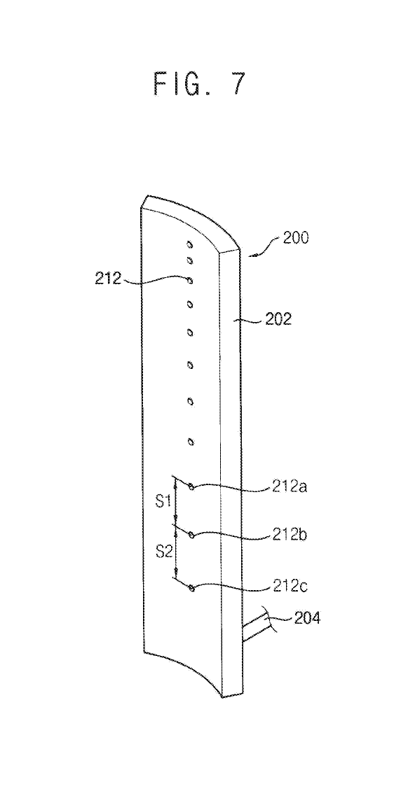

FIGS. 7 to 11 are perspective views illustrating gas injectors in accordance with some example embodiments.

Referring to FIG. 7, as a height of the ejection hole 212 from the gas introduction tube 204 is increased, a distance between the adjacent ejection holes 212 may be decreased. The ejection holes 212 may have a circular shape. A first ejection hole 212a of a first height may be spaced apart by a first distance S1 from a second ejection hole 212b of a second height lower than the first height, and the second ejection hole 212b of the second height may be spaced apart by a second distance S2 greater than the first distance S1 from a third ejection hole 212c of a third height lower than the second height.

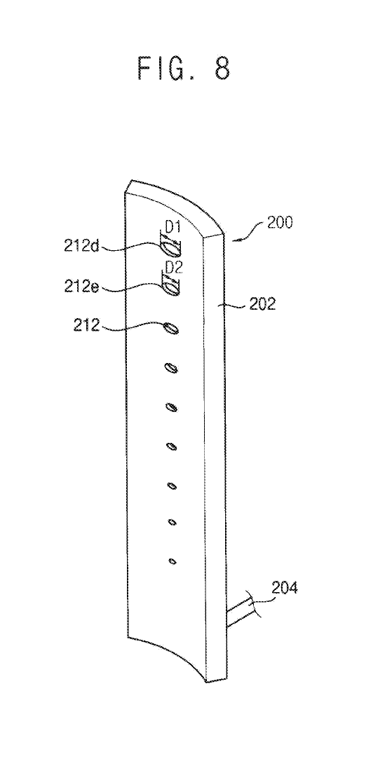

Referring to FIG. 8, as a height of the ejection hole 212 from the gas introduction tube 204 is increased, a size of the ejection hole 212 may be increased. The ejection holes 212 may have an oval shape. An ejection hole 212d of a first height may have a first diameter D1, and an ejection hole 212e of a second height lower than the first height may have a second diameter D2 smaller than the first diameter D1.

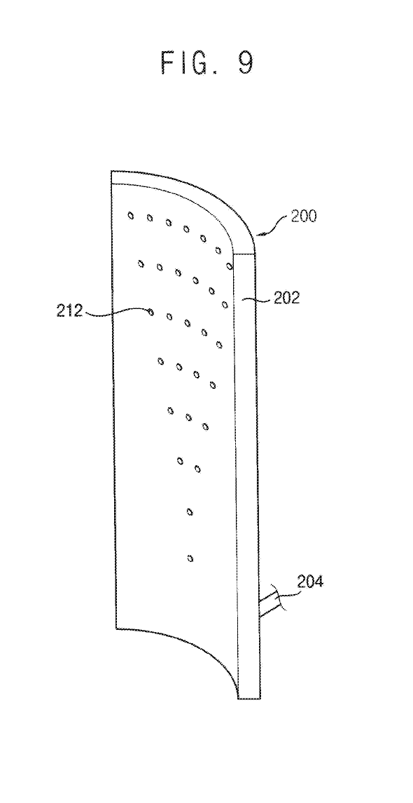

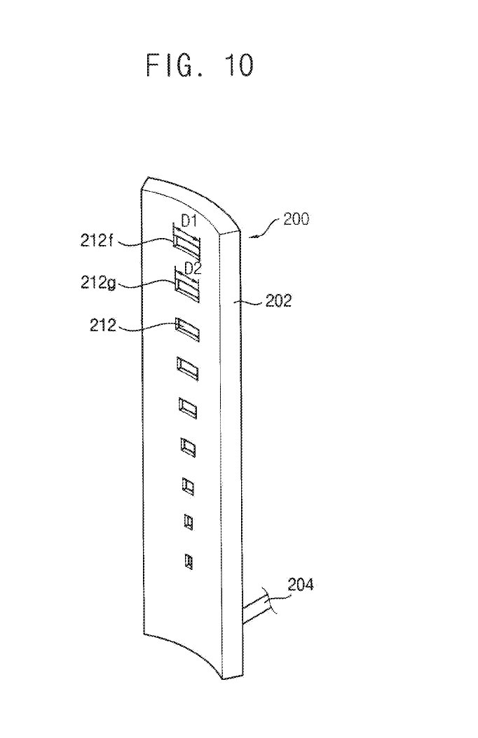

Referring to FIG. 9, a plurality of the ejection holes 212 may be disposed at the same height from the gas introduction tube 204. As a height of the ejection hole 212 from the gas introduction tube 204 is increased, the number of the ejection holes 212 disposed at the same height may be increased. For example, the number of the ejection holes at a first height from the gas introduction tube 204 may be greater than the number of the ejection holes at a second height lower than the first height.

Referring to FIG. 10, as a height of the ejection hole 212 from the gas introduction tube 204 is increased, a size of the ejection hole 212 may be increased. The ejection holes 212 may have a rectangular shape. An ejection hole 212f of a first height may have a first diameter D1, and an ejection hole 212g of a second height lower than the first height may have a second diameter D2 smaller than the first diameter D1.

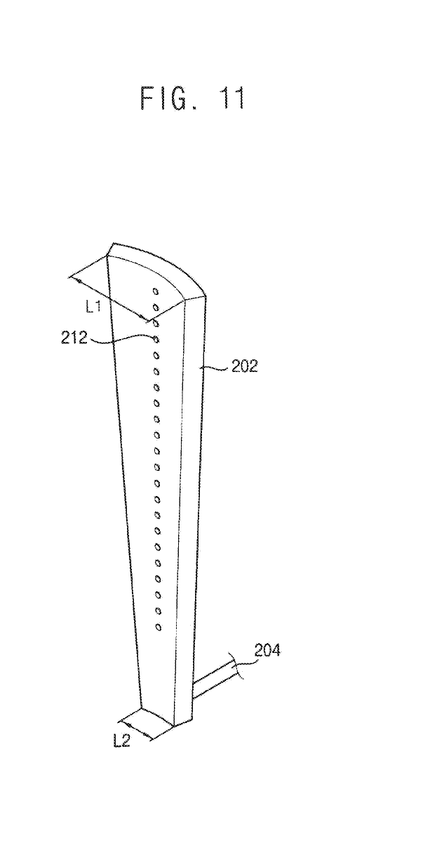

Referring to FIG. 11, a sectional area of the distributing path of the gas distributor 202 may be increased with a height in the gas distributor 202. The sectional area of the gas distributor 202 may become gradually greater from a bottom portion to a top portion thereof. The inner portion of the gas distributor 202 at the highest position may have a first length L1 in the circumferential direction, and the inner portion of the gas distributor 202 at the lowest position may have a second length L2 smaller than the first length L1 in the circumferential direction.

In some example embodiments, the wafer processing apparatus 100 may include an exhaust portion which exhausts a gas from the reaction chamber 102.

The exhaust portion may include an exhaust port 130 that is connected to a space in the reaction tube 110. The exhaust port 130 may be formed to penetrate through the support 120 in which the flange of the reaction tube 110 is installed. Accordingly, the gas in the reaction chamber 102 may flow out of the reaction tube 110 via the exhaust port 130.

In some example embodiments, the wafer processing apparatus 100 may include at least one gas nozzle for cleaning the reaction chamber 102. The gas nozzle may supply a cleaning gas and/or a purge gas. For example, the wafer processing apparatus 100 may include a first nozzle for supplying the cleaning gas and a second nozzle for supplying the purge gas.

In some example embodiments, after a certain number of ALD processes are performed in the reaction chamber 102 of the wafer processing apparatus 100, an in-situ cleaning process may be performed to remove a layer deposited on the reaction chamber 102.

As the deposition processes are performed repeatedly in the reaction chamber 102, by-products may be deposited excessively on the reaction chamber 102 and peel off to generate particles in the reaction chamber 102. Accordingly, after performing a certain number of the processes, whether or not perform a cleaning process for the reaction chamber 102 may be determined.

As mentioned above, the gas injector 200 may include the gas distributor 202 having an arc shape within the reaction tube 110 to surround the boat 150. Accordingly, a gas delivering volume of the gas injector 200 may be increased without space restriction between the reaction tube 110 and the boat 150, to thereby reduce a gas injection velocity difference between the upper and lower portions of the gas injector 200.

Even though an inner diameter of the reaction tube 110 is decreased to order to improve an ALD process variation, the circumferential length of the arc-shaped gas distributor 202 may be increased to thereby increase the total gas delivering volume. Accordingly, a pressure distribution between the upper and lower portions of the gas injector 200 may be improved such that an injection velocity through the ejection hole at a relatively higher position may be increased to reduce the gas injection velocity difference between the upper and lower portions. Thus, a uniformity of a deposition layer formed on the wafer W may be improved.

Further, in order to improve the process variation, a sectional area of the gas distributor 202, the diameters, the number and the spacing distances of the ejection holes, etc., may vary according to a height in the gas distributor 202 within the reaction tube 110.

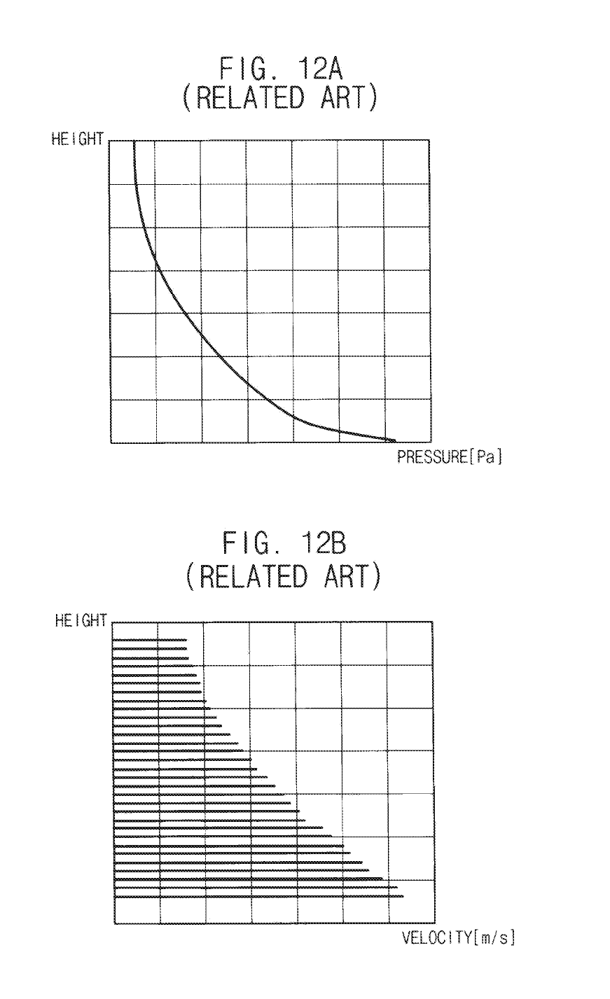

FIG. 12A is a graph illustrating an inner pressure according to a height in a related art gas injector; and FIG. 12B is a graph illustrating a gas ejection velocity according to a height in a related art gas injector.

Referring to FIGS. 12A and 12B, in a related art gas injector having a cylindrical rod shape, an inner pressure and an ejection velocity may be decreased with a height in the gas injector. Accordingly, a pressure difference and an ejection velocity difference between upper and lower portions of the gas injector may be relatively great, so that a process variation may be deteriorated.

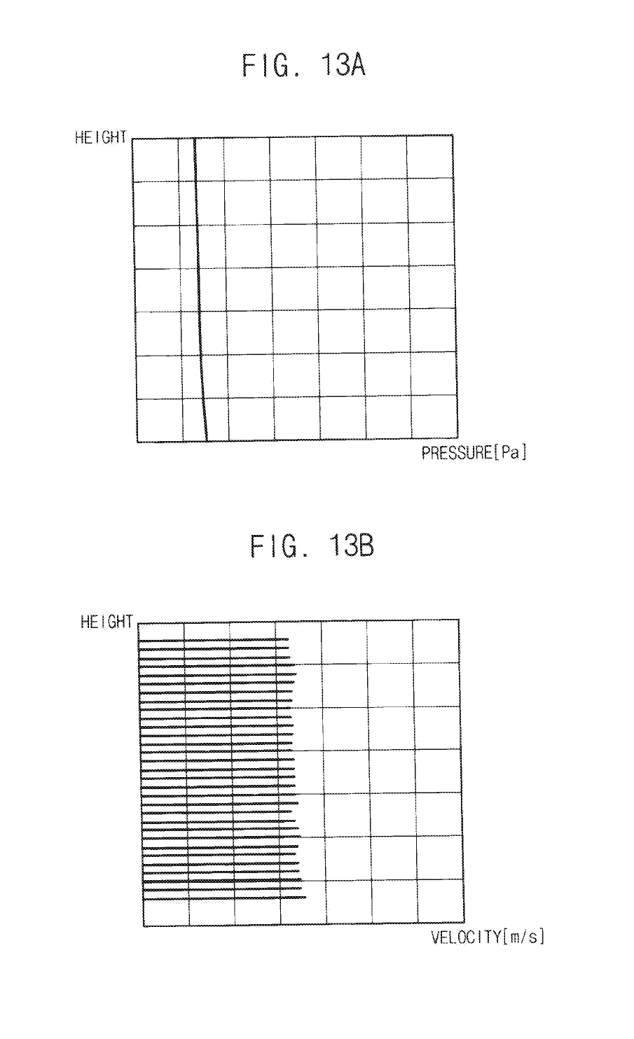

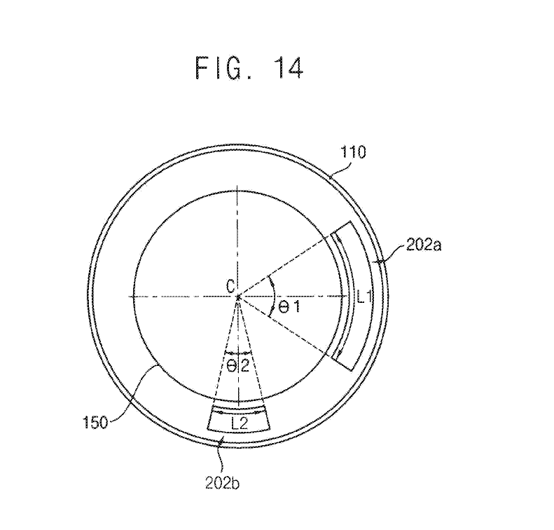

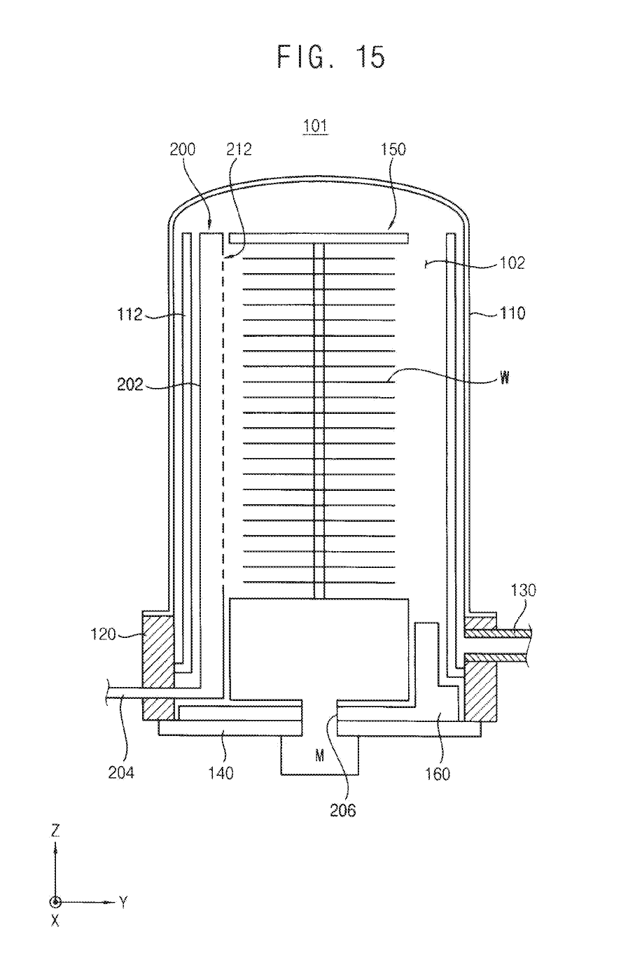

FIG. 13A is a graph illustrating an inner pressure according to a height in a gas injector in accordance with some example embodiments; and FIG. 13B is a graph illustrating a gas ejection velocity according to a height in a gas injector in accordance with some example embodiments.

Referring to FIGS. 13A and 13B, a gas injector may include a gas distributor having an arc shape to surround a boat within a reaction tube. A pressure difference and an ejection velocity difference between upper and lower portions of the gas injector may be relatively smaller than a related art gas injector, so that a process variation may be improved.

FIG. 14 is a plan view illustrating a gas injector within a reaction tube in accordance with some example embodiments.

Referring to FIG. 14, a gas injector may include a first gas distributor 202a and a second gas distributor 202b. The gas injector may include two gas distributors, however, the number of the gas distributors may not be limited thereto.

The first gas distributor 202a may be arranged in a reaction tube 110 to be spaced apart in the circumferential direction from the second gas distributor 202b. The first gas distributor 202a and the second gas distributor 202b may extend in the vertical direction from a common gas introduction tube under the reaction tube 110, respectively. Alternatively, the first gas distributor 202a and the second gas distributor 202b may be connected to separate first and second gas introduction tubes, respectively.

The first gas distributor 202a may extend in the circumferential direction to form a first central angle θ1 at the center C of the reaction tube 110, and the second gas distributor 202b may extend in the circumferential direction to form a second central angle θ2 the same as or different from the first central angle θ1 at the center C of the reaction tube 110. An arc length of the first gas distributor 202a may be the same as or different from an arc length of the second gas distributor 202b.

For example, the first gas distributor 202a may have a first arc length L1, and a second gas distributor 202b may have a second arc length L2 smaller than the first arc length L1. In this case, the first central angle θ1 may be greater than the second central angle θ2.

FIG. 15 is a cross-sectional view illustrating a wafer processing apparatus in accordance with some example embodiments. The wafer processing apparatus may be substantially the same as or similar to the apparatus described with reference to FIG. 1, except for an inner tube. Thus, the same reference numerals will be used to refer to the same or like elements as those described in the apparatus described with reference to FIG. 1, and any further repetitive explanation concerning the above elements will be omitted.

Referring to FIG. 15, a wafer processing apparatus 101 may further include an inner tube disposed within a reaction tube 110 to define a reaction chamber 102. The wafer processing apparatus 101 may include a dual tube type batch reactor having a reaction tube 110 and an inner tube 112.

A lower portion of the inner tube 112 may include an open end, and an upper portion of the inner tube 112 may include an open end. Alternatively, the upper portion of the inner tube 112 may include a closed end. The inner tube 112 may extend in a vertical direction to define the reaction chamber 102 of the reactor. The reaction chamber 102 may receive a boat 150 that holds a plurality of the wafers W that are spaced apart in the vertical direction.

A gas distributor 202 of a gas injector 200 may extend in the vertical direction within the inner tube 112 from a gas introduction tube 204, and may extend in the circumferential direction of the inner tube 112 in an arc shape.

In some example embodiments, an exhaust slit may be formed in a sidewall of the inner tube 112. The exhaust slit may extend along the extending direction of the inner tube 112. For example, the exhaust slit may have a width of about 20 mm to about 30 mm.

An exhaust portion may exhaust a gas from the reaction chamber 102 via an exhaust space between the reaction tube 110 and the inner tube 112. The exhaust portion may include an exhaust port 130 that is connected to the exhaust space between an inner surface of the reaction tube 110 and an outer surface of the inner tube 112. The exhaust port 130 may be formed to penetrate through a support 120 in which the flange of the reaction tube 110 is installed.

Accordingly, the gas in the reaction chamber 102 may flow out of the inner tube 112 through the exhaust slit, and then flow through the exhaust space between the reaction tube 110 and the inner tube 112 to be exhausted via the exhaust port 130.

Hereinafter, a method of processing a plurality of wafers using the wafer processing apparatus in FIG. 1, and a method of manufacturing a semiconductor device using the same will be explained.

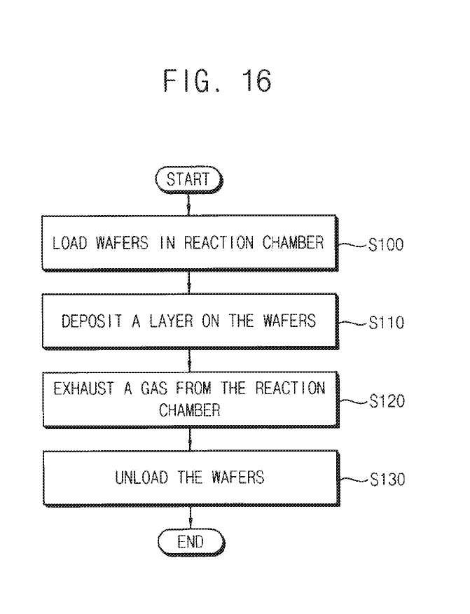

FIG. 16 is a flow chart illustrating a method of processing a wafer in accordance with some example embodiments. The method may be used to form a silicon oxide layer or a silicon nitride layer on a wafer in an atomic layer deposition process. However, example embodiments should not be construed as limited thereto.

Referring to FIGS. 1, 3, 4, and 16, a plurality of wafers W may be loaded into a reaction chamber 102 of a wafer processing apparatus 100 (S100).

A reaction tube 110 of the wafer processing apparatus 100 may extend in a vertical direction to define a reaction chamber 102. A stand-by chamber (not shown) may be disposed under the reaction chamber 102 and may be arranged in the vertical direction. After the wafers W are loaded into a boat 150, the boat 150 may be raised and loaded into the reaction chamber 102 by a driving unit (not shown).

Then, a reaction gas may be supplied toward the wafers W through ejection holes 212 of a gas injector 200, respectively, to deposit a layer on the wafers W (S110).

The gas distributor 202 of the gas injector 200 may extend in the vertical direction between the reaction tube 110 and the boat 150. The gas distributor 202 may extend in the circumferential direction of the reaction tube 110 in arc shape to surround the boat 150.

The reaction gas may be ejected toward the center C of the reaction tube 110 via a plurality of the ejection holes 212 which are formed in the inner surface of the gas injector 200. For example, the reaction gas may include a source gas for forming a blocking layer, a charge storage layer, and a tunnel insulation layer of a cell transistor of VNAND. Additionally, a pulse gas or a cleaning gas may be supplied into the reaction chamber 102. Accordingly, an ALD process may be performed to form an insulation layer such as silicon oxide or silicon nitride layer on each of the wafers W.

Then, a gas may be exhausted from the reaction chamber 102 (S120).

The gas in the reaction chamber 102 may be exhausted from the reaction tube 110 through an exhaust port that is formed in a support 120.

After forming the layer having a desired thickness (that may or may not be predetermined) on the wafers W, the wafers W may be unloaded from the reaction chamber 102 (S130).

In some example embodiments, after the deposition process including the steps S100, S110, S120, and S130 are completed, whether or not to perform a cleaning process in the reaction chamber 102 may be determined (S140) (not shown). When it is determined that the cleaning process is not required to be performed, the deposition process including the steps S100, S110, S120, and S130 may be performed again.

Hereinafter, a method of manufacturing a semiconductor device using the wafer processing method in FIG. 16 will be explained.

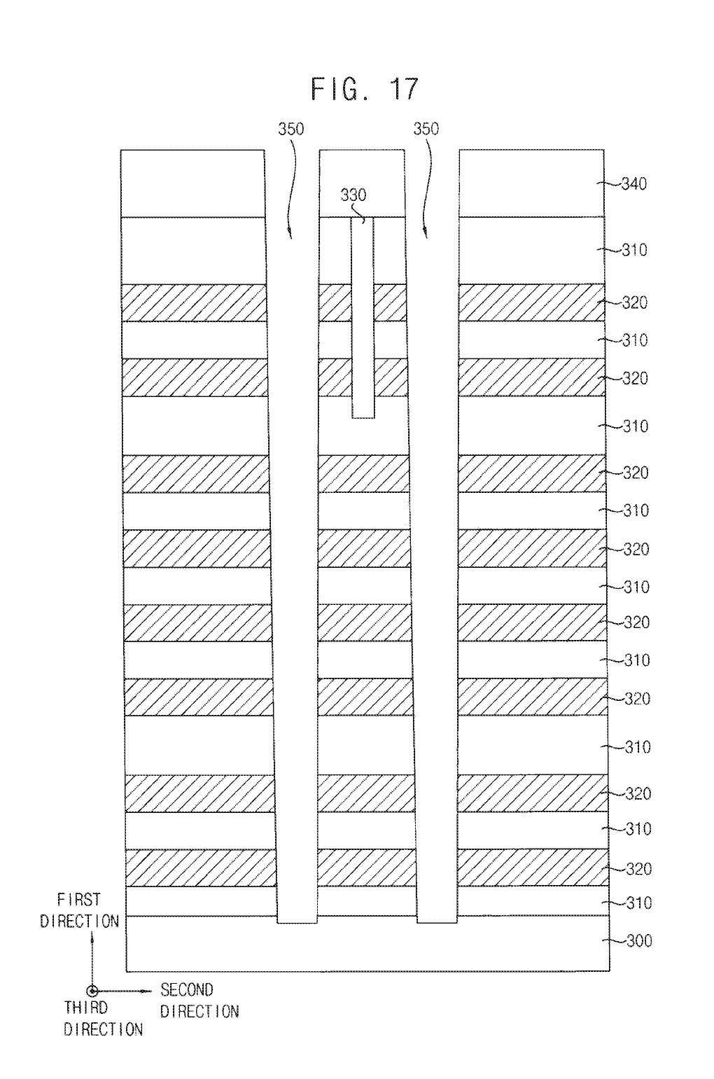

FIGS. 17 to 26 are vertical cross-sectional views illustrating a method of manufacturing a vertical memory device in accordance with some example embodiments. In all figures in this specification, a direction substantially perpendicular to a top surface of a substrate is referred to as a first direction, and two directions substantially parallel to the top surface of the substrate and substantially perpendicular to each other are referred to as a second direction and a third direction. Additionally, a direction indicated by an arrow in the figures and a reverse direction thereto are considered as the same direction. The definition of the direction mentioned above is identical in all figures.

Referring to FIG. 17, a first insulation layer 310 and a sacrificial layer 320 may be alternately and repeatedly formed on a substrate 300 and, thus, a plurality of first insulation layers 310 and a plurality of sacrificial layers 320 may be alternately formed on each other at a plurality of levels in the first direction, respectively. The substrate 300 may include a semiconductor material, for example, silicon and/or germanium.

In some example embodiments, the first insulation layers 310 and the sacrificial layers 320 may be formed by, for example, a chemical vapor deposition (CVD) process, a plasma enhanced chemical vapor deposition (PECVD) process, an atomic layer deposition process (ALD) process, etc. A lowermost first insulation layer 310, which may be formed directly on a top surface of the substrate 300, may be formed by, for example, a thermal oxidation process.

In some example embodiments, the first insulation layer 310 may be formed to include a silicon oxide, and the first sacrificial layer 320 may be formed to include, for example, a material with an etch selectivity to the first insulation layer 310 (e.g., silicon nitride and/or silicon boron nitride).

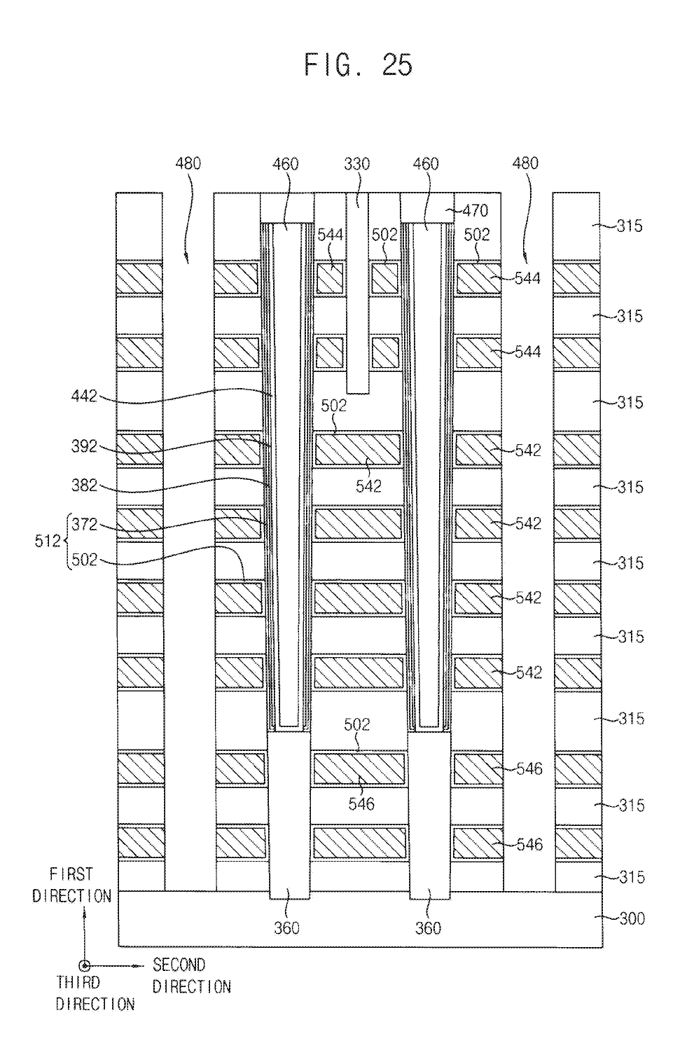

The number of the first insulation layers 310 and the number of the sacrificial layers 320 stacked on the substrate 300 may vary according to the desired stacked number of a ground select line (GSL) 546 (refer to FIG. 25), a word line 542 (refer to FIG. 25), and a string select line (SSL) 544 (refer to FIG. 25). According to some example embodiments, each of the GSL 546 and the SSL 544 may be formed at 2 levels, and the word line 542 may be formed at 4 levels. Thus, the sacrificial layer 320 may be formed at 8 levels, and the first insulation layer 310 may be formed at 9 levels. However, example embodiments of the number of the first insulation layers 310 and the number of the sacrificial layers 320 stacked on the substrate 300 may not be limited thereto and, for example, each of the GSL 546 and the SSL 544 may be formed at a single level, and the word line 542 may be formed at 2, 8, or 16 levels. In this case, the sacrificial layers 320 may be formed at 4, 10, or 18 levels, and the first insulation layer 310 may be formed at 5, 11, or 19 levels.

Then, a trench may be formed partially through the first insulation layers 310 and the sacrificial layers 320, and a division layer pattern 330 filling the trench may be formed.

In some example embodiments, the trench may be formed by a photolithography process. The trench may be formed through the sacrificial layers 320 in which the SSL 544 may be formed in a subsequent process and the first insulation layers 310 thereon, and further partially through the first insulation layer 310 therebeneath. In some example embodiments, the trench may be formed to extend in the third direction.

A division layer may be formed on the first insulation layer 310 to sufficiently fill the trench, and may be planarized until a top surface of an uppermost first insulation layer 310 may be exposed to form the division layer pattern 330.

Then, a plurality of holes 350 may be formed through the first insulation layers 310 and the sacrificial layers 320 to expose a top surface of the substrate 300.

In some example embodiments, after forming a hard mask 340 on the uppermost first insulation layer 310, the first insulation layers 310 and the sacrificial layers 320 may be dry etched using the hard mask 340 as an etch mask to form the holes 350. Thus, the holes 350 may be formed to extend in the first direction. In other words, each of the holes 350 may be formed to include a sidewall profile substantially perpendicular to the top surface of the substrate 300. Due to the characteristics of a dry etch process, the holes 350 may be of a width that becomes gradually smaller from a top portion to a bottom portion thereof and, thus, the sidewall profile may not be completely perpendicular to the top surface of the substrate 300, which is not shown.

In some example embodiments, the hard mask 340 may be formed to include a material with an etch selectivity to silicon oxide and silicon nitride that may be included in the first insulation layers 310 and the sacrificial layers 320, respectively (e.g., polysilicon or amorphous silicon by a CVD process, a PECVD process, an ALD process, and the like).

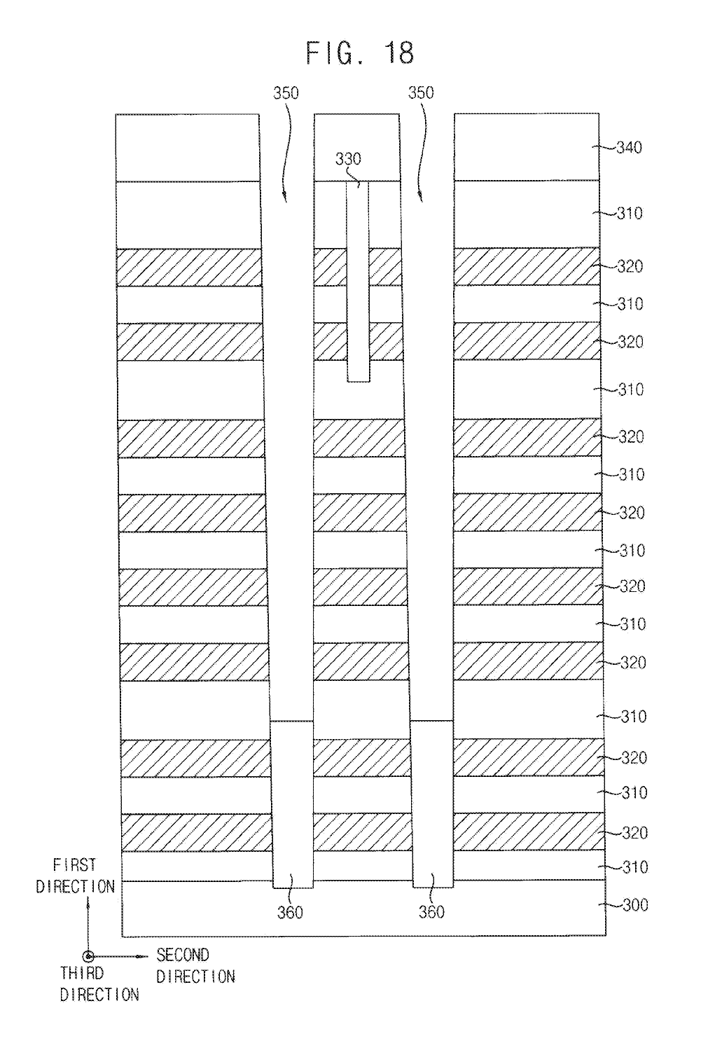

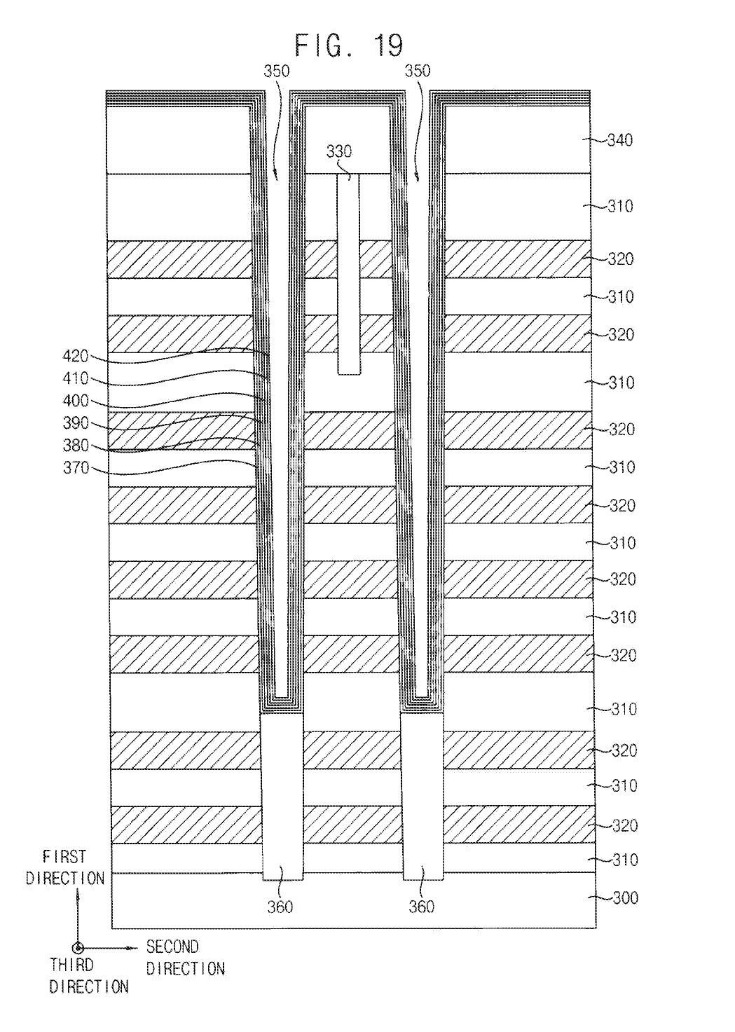

Referring to FIG. 18, a semiconductor pattern 360 may be formed to partially fill each of the holes 350.

Particularly, a selective epitaxial growth (SEG) process may be performed using the exposed top surface of the substrate 300 as a seed to form the semiconductor pattern 360 partially filling the holes 350. Thus, the semiconductor pattern 360 may be formed to include single crystalline silicon or single crystalline germanium according to the material of the substrate 300 and, in some cases, impurities may be doped hereinto. Alternatively, an amorphous silicon layer may be formed to fill the holes 350, and a laser epitaxial growth (LEG) process or a solid phase epitaxy (SPE) process may be performed on the amorphous silicon layer to form the semiconductor pattern 360. In some example embodiments, the semiconductor pattern 360 may be formed to have the top surface higher than that of the sacrificial layer 320 in which the GSL 546 may be formed subsequently.

Referring to FIG. 19, a first blocking layer 370, a charge storage layer 380, a tunnel insulation layer 390, a first channel layer 400, an etch stop layer 410, and a spacer layer 420 may be sequentially formed on sidewalls of the holes 350, the top surface of the semiconductor pattern 360, and a top surface of the hard mask 340.

As illustrated in FIGS. 1 and 16, after the substrate 300 is loaded into the boat 150, the boat 150 may be raised and loaded into the reaction chamber 102 of the wafer processing apparatus 100. Then, a reaction gas for a deposition process may be supplied toward the substrate 300 through the ejection holes 212 of the gas distributor 202 having an arc shape. Accordingly, ALD processes may be performed to form the first blocking layer 370, the charge storage layer 380, and the tunnel insulation layer 390 having uniform thicknesses may be sequentially formed on the substrate 300.

In some example embodiments, the first blocking layer 370 may be formed to include an oxide (e.g., silicon oxide), the charge storage layer 380 may be formed to include a nitride (e.g., silicon nitride), and the tunnel insulation layer 390 may be formed to include an oxide (e.g., silicon oxide).

In some example embodiments, the first channel layer 400 may be formed to include doped or undoped polysilicon, or amorphous silicon. When the first channel layer 400 is formed to include amorphous silicon, an LEG process or an SPE process may be further performed so that the amorphous silicon layer may be changed to a crystalline silicon layer.

In some example embodiments, the etch stop layer 410 may be formed to include substantially the same material as the first blocking layer 370 (e.g., silicon oxide), and the spacer layer 420 may be formed to include substantially the same material as the charge storage layer 380 (e.g., silicon nitride).

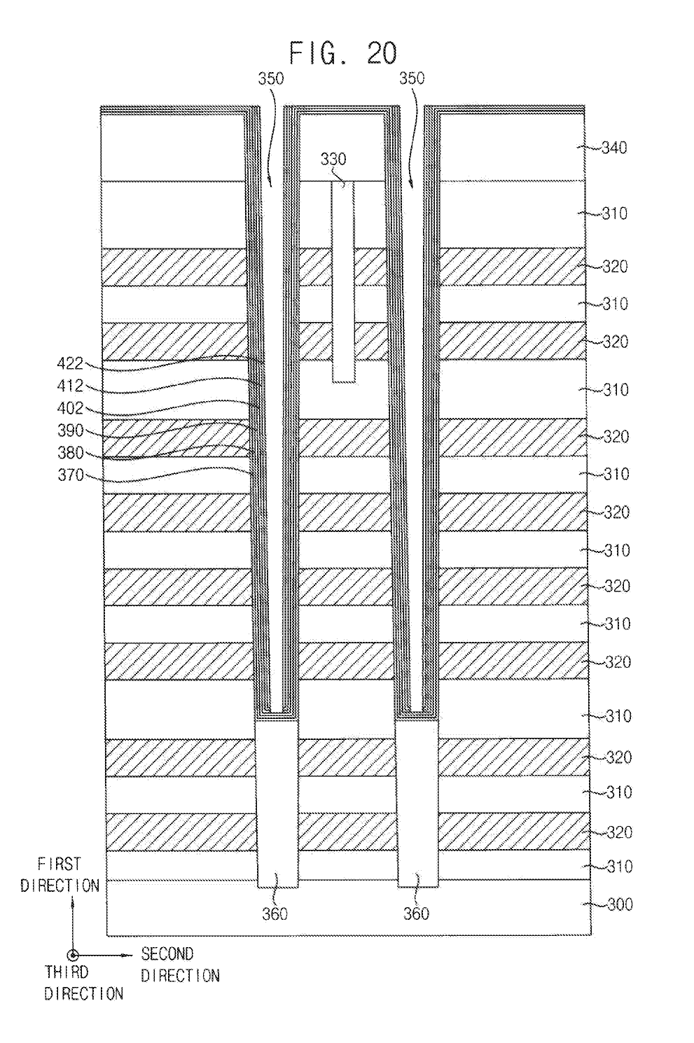

Referring to FIG. 20, a portion of the spacer layer 420 on the top surface of the semiconductor pattern 360 may be removed by etching the spacer layer 420 anisotropically to form a spacer 422 on the sidewall of each of the holes 350, and the etch stop layer 410 and the first channel layer 400 may be etched using the spacer 422 as an etch mask to form an etch stop layer pattern 412 and a first channel 402, respectively, exposing a portion of the tunnel insulation layer 390. In other words, portions of the etch stop layer 410 and the first channel layer 400 formed on the central top surface of the semiconductor pattern 360 and a top surface of the hard mask 340 may be removed.

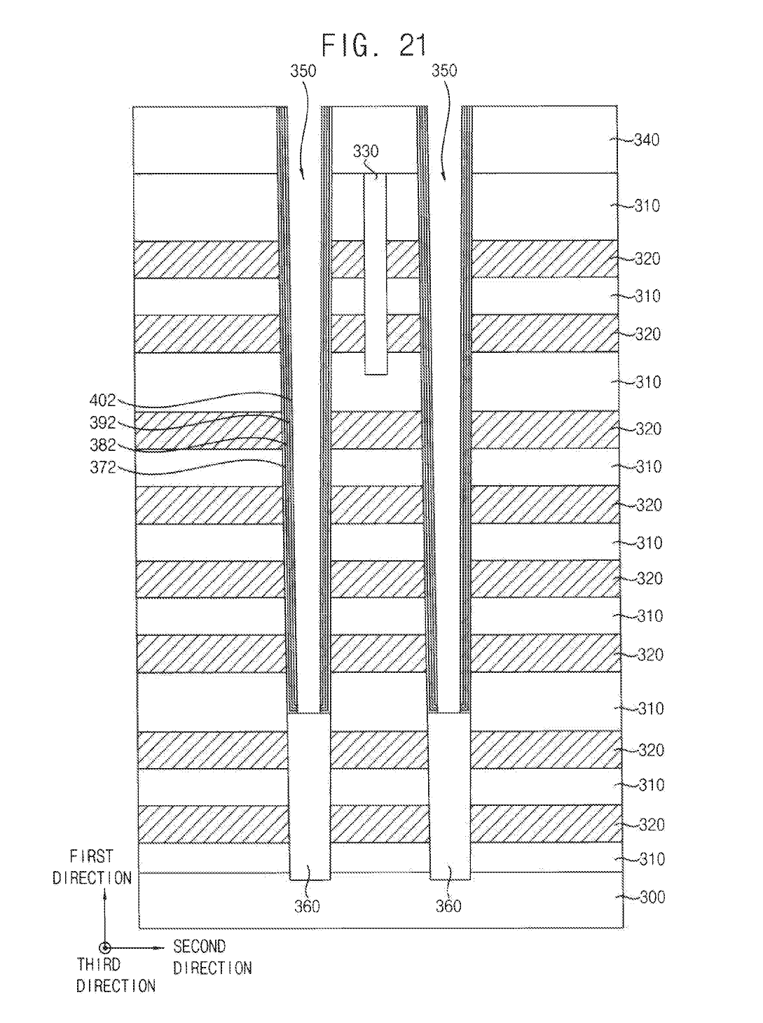

Referring to FIG. 21, an exposed portion of the tunnel insulation layer 390 and the charge storage layer 380 therebeneath may be removed to form a tunnel insulation layer pattern 392 and a charge storage layer pattern 382 and, thus, a portion of the first blocking layer 370 may be exposed.

In some example embodiments, the tunnel insulation layer 390 and the charge storage layer 380 may be etched by a wet etch process. In other words, the tunnel insulation layer 390 including a silicon oxide may be etched using hydrofluoric acid as an etching solution, and the charge storage layer 380 including a silicon nitride may be etched using phosphoric acid or sulfuric acid as an etching solution. The spacer 422 including a silicon nitride may be also etched to expose the first channel 402.

In some example embodiments, the first blocking layer 370 including a silicon oxide may be etched by a wet etch process using an etch solution including hydrofluoric acid. The first channel 402 may include a different material from the first blocking layer 370 and, therefore, portions of the tunnel insulation layer pattern 392, the charge storage layer pattern 382, and the first blocking layer 370 formed underneath may be protected by the first channel 402.

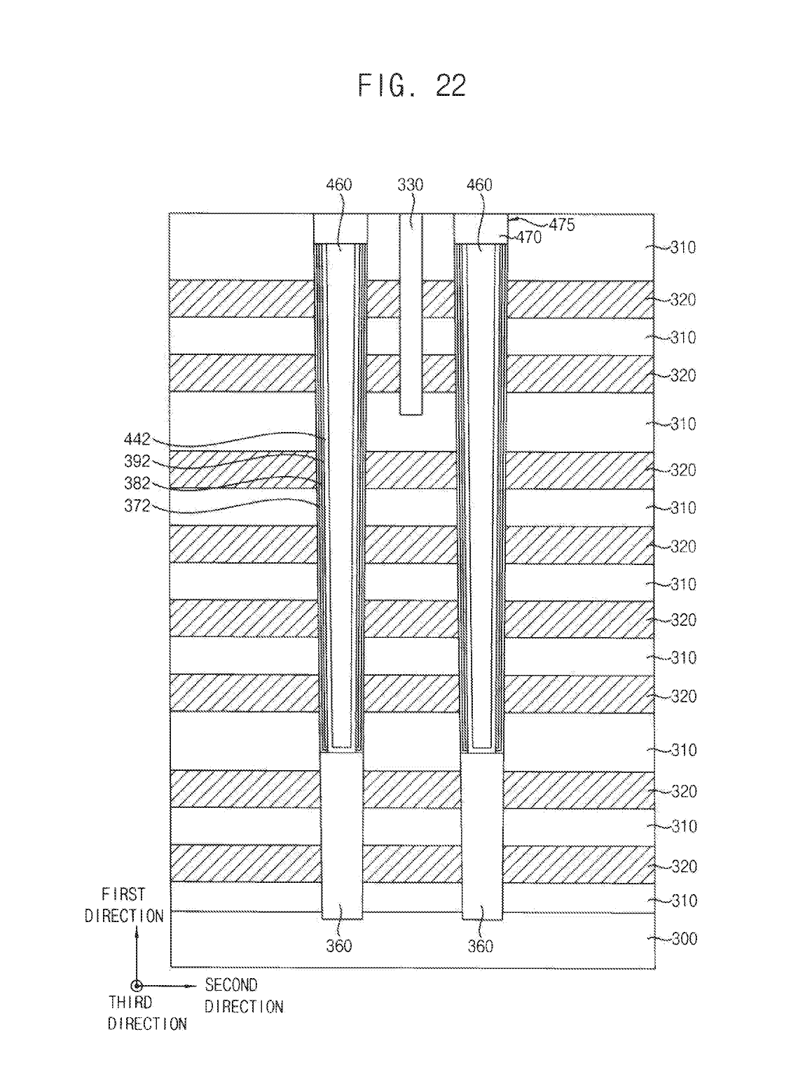

Referring to FIG. 22, a second channel layer may formed on the first channel 402, the exposed central top surface of the semiconductor pattern 360, and the hard mask 340.

In some example embodiments, the second channel layer may be formed using the substantially the same material as the first channel 402 and, thus, the first channel 402 and the second channel layer may be merged into one layer, which may be simply referred to as a second channel layer hereinafter.

Then, after a second insulation layer filling a remaining portion of the holes 350 sufficiently may be formed on the second channel layer, the second insulation layer, the second channel layer, the tunnel insulation layer pattern 392, the charge storage layer pattern 382, a first blocking layer pattern 372, and the hard mask 340 may be planarized until a top surface of a pattern of an uppermost first insulation layer 310 may be exposed to form a second insulation layer pattern 460 filling the remaining portion of the holes 350, and the second channel layer may be transformed into a channel 442.

Thus, the first blocking layer pattern 372, the charge storage layer pattern 382, the tunnel insulation layer pattern 392, the channel 442, and the second insulation layer pattern 460 may be formed sequentially on the top surface of the semiconductor pattern 360 in each hole 350.

Then, an upper portion of the first structure (i.e., upper portions of the second insulation layer pattern 460, the channel 442, the tunnel insulation layer pattern 392, the charge storage layer pattern 382, and the first blocking layer pattern 372) may be removed to form a second recess 475, and a pad 470 may be formed to fill the second recess 475.

The pad 470 may be formed on each channel 442 and, thus, may form a pad array in accordance with the channel array.

The first structure, the semiconductor pattern 360 and the pad 470 in each of the holes 350 may form a second structure.

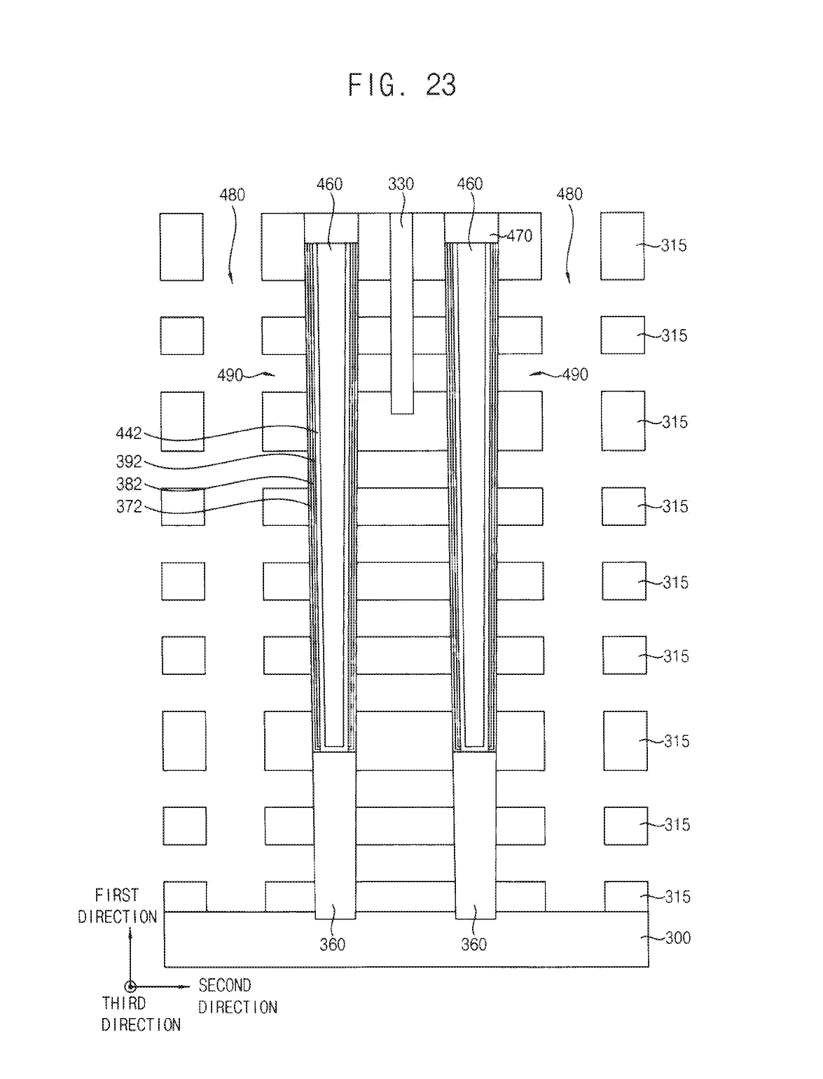

Referring to FIG. 23, a first opening 480 may be formed through the first insulation layers 310 and the sacrificial layers 320 to expose a top surface of the substrate 300.

In some example embodiments, after forming a hard mask (not shown) on the uppermost first insulation layer 310, the insulation layers 310 and the sacrificial layers 320 may be, for example, dry etched using the hard mask as an etch mask to form the first opening 480. The first opening 480 may be formed to extend in the first direction.

In some example embodiments, a plurality of first openings 480 may be formed in the second direction, and each first opening 480 may be extended in the third direction. The first insulation layers 310 and the sacrificial layers 320 may be transformed into first insulation layer pattern 315 and a sacrificial layer pattern, respectively. A plurality of first insulation layer patterns 315 and a plurality of sacrificial layer patterns may be formed in the second direction at each level, and each first insulation layer pattern 315 and each sacrificial layer pattern may be extended in the third direction.

Then, the sacrificial layer patterns may be removed to form a gap 490 between the first insulation layer patterns 315 at adjacent levels, and portions of an outer sidewall of the first blocking layer pattern 372 and a sidewall of the semiconductor pattern 360 may be exposed by the gap 490. In some example embodiments, the sacrificial layer patterns exposed by the first opening 480 may be removed by, for example, a wet etch process using an etching solution including phosphoric acid and/or sulfuric acid.

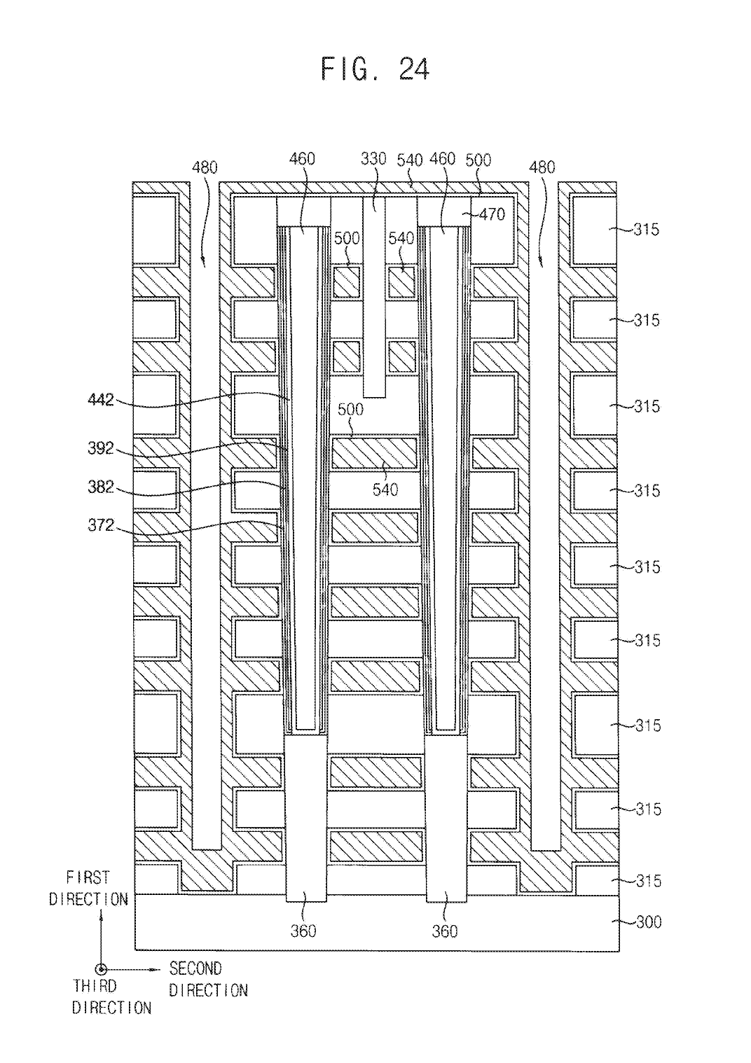

Referring to FIGS. 24 and 25, a second blocking layer 500 may be formed on the exposed portion of the outer sidewall of the first blocking layer pattern 372, the exposed portion of the sidewall of the semiconductor pattern 360, an inner wall of the gap 490, a surface of the first insulation layer pattern 315, the exposed top surface of the substrate 300, a top surface of the pad 470, and a top surface of the division layer pattern 330, and a gate electrode layer 540 may be formed on the second blocking layer 500 to sufficiently fill remaining portions of the gap 490.

In some example embodiments, the second blocking layer 500 may be formed to include, for example, a metal oxide. For example, the metal oxide may include aluminum oxide, hafnium oxide, lanthanum oxide, lanthanum aluminum oxide, lanthanum hafnium oxide, hafnium aluminum oxide, titanium oxide, tantalum oxide and/or zirconium oxide.

In some example embodiments, the gate electrode layer 540 may be formed to include a metal and/or a metal nitride. For example, the gate electrode layer 540 may be formed using a metal having a low electric resistance (e.g., tungsten, titanium, tantalum, platinum, etc.), and a metal nitride (e.g., titanium nitride, tantalum nitride, etc.).

Then, the gate electrode layer 540 may be partially removed to form gate electrodes 542, 544, and 546 in the gap 490. In some example embodiments, the gate electrode layer 540 may be partially removed through a wet etch process.

In some example embodiments, the gate electrodes 542, 544 and 546 may be formed to extend in the third direction, and include the GSL 546, the word line 542, and the SSL 544 sequentially formed in the first direction from the a top surface of the substrate 300. Each of the GSL 546, the word line 542 and the SSL 544 may be formed at a single level or at a plurality of levels. In some example embodiments, each of the GSL 546 and the SSL 544 may be formed at 2 levels, and the word line 542 may be formed at 4 levels between the GSL 546 and the SSL 544. The GSL 546 may be formed adjacent to the semiconductor pattern 360, and the word line 542 and the SSL 544 may be formed adjacent to the channels 442 and, particularly, the SSL 544 may be formed adjacent to the division layer pattern 330.

When the gate electrode layer 540 is partially removed, portions of the second blocking layer 500 on the surface of the first insulation layer pattern 315 and on the top surfaces of the substrate 300, the pad 470, and the division layer pattern 330 may also be removed to form a second blocking layer pattern 502. The first and second blocking layer patterns 372 and 502 may define a blocking layer pattern structure 512.

In a process in which the gate electrode layer 540 and the second blocking layer 500 are partially removed, the first opening 480 exposing a top surface of the substrate 300 and being extended in the third direction may be formed again, and impurities may be implanted into the exposed top surface of the substrate 300 to form an impurity region 305. In some example embodiments, the impurities may include n-type impurities (e.g., phosphorus, arsenic, etc.). In some example embodiments, the impurity region 305 may be formed to extend in the third direction and serve as a common source line (CSL).

A metal silicide pattern (not shown) (e.g., a cobalt silicide pattern or a nickel silicide pattern) may be further formed on the impurity region 305.

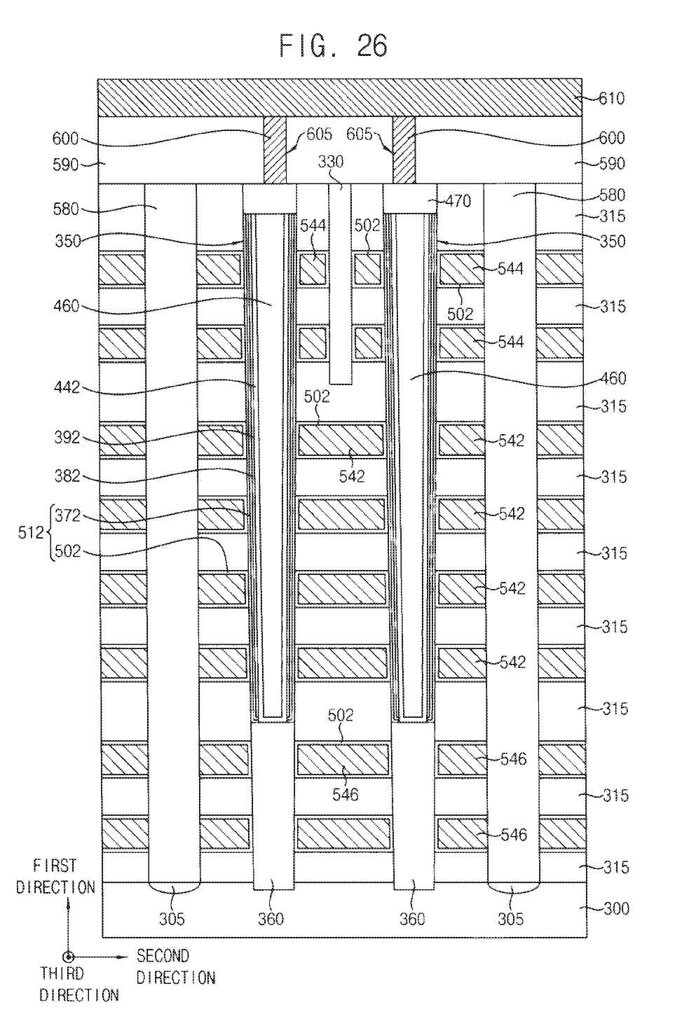

Referring to FIG. 26, a third insulation layer pattern 580 filling the first opening 480 may be formed. In some example embodiments, after the third insulation layer pattern 580 filling the first opening 480 is formed on the substrate 300 and the uppermost first insulation layer pattern 315, the third insulation layer may be planarized until a top surface of the uppermost first insulation layer pattern 315 may be exposed to form a third insulation layer pattern 580.

Then, a fourth insulation layer 590 may be formed on the first and third insulation layer patterns 315 and 580, the pad 470, and the division layer pattern 330, and a second opening 605 may be formed to expose a top surface of the pad 470. In some example embodiments, a plurality of second openings 605 corresponding to the pads 470 may be formed to define a second opening array.

Then, a bit line contact 600 may be formed on the pad 470 to fill the second opening 605, and a bit line 610 electrically connected to the bit line contact 600 may be formed to complete the vertical memory device. The bit line 610 and the bit line contact 600 may be formed to include, for example, a metal, a metal nitride, and/or doped polysilicon.

In some example embodiments, a plurality of bit line contacts 600 corresponding to the pads 470 may be formed to define a bit line contact array, a plurality of bit lines 610 may be formed in the third direction, and each bit line 610 may be formed to extend in the second direction.

It should be understood that the example embodiments described herein should be considered in a descriptive sense only and not for purposes of limitation. Descriptions of features or aspects within each embodiment should typically be considered as available for other similar features or aspects in other embodiments.

Although example embodiments have been shown and described, it would be appreciated by those skilled in the art that changes may be made in these example embodiments without departing from the principles and spirit of the disclosure, the scope of which is defined by the claims and their equivalents.

1. A gas injector, comprising:
a gas introduction tube configured to introduce reaction gas into a reaction tube from a gas supply source; and
a gas distributor connected to the gas introduction tube, extending from the gas introduction tube in a direction within the reaction tube, including a plurality of ejection holes in an inner surface of the gas distributor, and having an arc shape extending in a circumferential direction of the reaction tube;
wherein the ejection holes are spaced apart from each other in the extending direction of the gas distributor, and are configured to spray the reaction gas.

2. The gas injector of claim 1, wherein the gas distributor comprises an arc-shaped inner portion, spaced apart by a first radius from a center of the reaction tube, and an arc-shaped outer portion, spaced apart by a second radius greater than the first radius from the center of the reaction tube, and
wherein the inner portion and the outer portion form a distributing path for the reaction gas therebetween.

3. The gas injector of claim 2, wherein the ejection holes are formed in the inner portion to be spaced apart from each other in the extending direction.

4. The gas injector of claim 1, wherein the ejection holes have a circular, oval, or polygonal shape.

5. The gas injector of claim 1, wherein as height of a respective ejection hole of the plurality of ejection holes from the gas introduction tube is increased, size of the respective ejection hole is increased.

6. The gas injector of claim 1, wherein a plurality of the ejection holes is at a same height from the gas introduction tube.

7. The gas injector of claim 6, wherein as the height of a respective ejection hole of the plurality of ejection holes from the gas introduction tube is increased, a number of the ejection holes at that same height is increased.

8. The gas injector of claim 1, wherein as height of a respective ejection hole of the plurality of ejection holes from the gas introduction tube is increased, a distance between adjacent ejection holes at that same height is decreased.

9. The gas injector of claim 1, wherein a sectional area of a gas distributing path of the gas distributor is increased with height in the gas distributor.

10. The gas injector of claim 1, wherein the ejection holes are configured to extend in a radial direction perpendicular to the extending direction of the gas distributor.

11.-25. (canceled)

26. A gas injector, comprising:
a gas introduction tube configured to introduce reaction gas, from a gas supply source, into a reaction tube; and
a gas distributor, configured to receive the reaction gas from the gas introduction tube and configured to distribute the reaction gas in the reaction tube via a plurality of ejection holes in the gas distributor;
wherein the ejection holes are in an inner surface of the gas distributor, and
wherein the ejection holes are spaced apart from each other in an extending direction of the gas distributor in the reaction tube.

27. The gas injector of claim 26, wherein at least two of the ejection holes are at a same distance along the extending direction of the gas distributor in the reaction tube.

28. The gas injector of claim 26, wherein at least two of the ejection holes are at a same distance from the gas introduction tube.

29. The gas injector of claim 26, wherein the ejection holes are also spaced apart from each other in a direction perpendicular to the extending direction of the gas distributor in the reaction tube.

30. The gas injector of claim 29, wherein at least two of the ejection holes are at a same distance along the direction perpendicular to the extending direction of the gas distributor in the reaction tube.

31. A gas injector, comprising:
a gas introduction tube configured to introduce reaction gas, from a gas supply source, into a reaction tube; and
a gas distributor, configured to receive the reaction gas from the gas introduction tube and configured to distribute the reaction gas in the reaction tube via a plurality of ejection holes in the gas distributor;
wherein the ejection holes are in an inner surface of the gas distributor, and
wherein the ejection holes are spaced apart from each other in a direction parallel to an axial direction of the reaction tube.

32. The gas injector of claim 31, wherein at least two of the ejection holes are at a same distance along the gas distributor in the direction parallel to the axial direction of the reaction tube.

33. The gas injector of claim 31, wherein at least two of the ejection holes are at a same distance from the gas introduction tube.

34. The gas injector of claim 31, wherein the ejection holes are also spaced apart from each other in a direction perpendicular to the direction parallel to the axial direction of the reaction tube.

35. The gas injector of claim 34, wherein at least two of the ejection holes are at a same distance along the direction perpendicular to the direction parallel to the axial direction of the reaction tube.
